(19) United States
(12) Patent Application Publication
(10) Pub. No.: US 2009/0059648 A1
(43) Pub. Date: Mar. 5, 2009

(54) FERROELECTRIC SEMICONDUCTOR STORAGE DEVICE

(75) Inventor: Susumu SHUTO, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/201,349

(22) Filed: Aug. 29, 2008

(30) Foreign Application Priority Data
Aug. 30, 2007 (JP) 2007-223974

(51) Int. Cl. G11C 11/22; G11C 11/24; G11C 11/409

(52) U.S. Cl. 365/145; 365/149; 365/189.011

(57) ABSTRACT

This ferroelectric semiconductor storage device includes: a ferroelectric capacitor; and a transistor having one end of its current path connected to one electrode of the ferroelectric capacitor. A plate line is connected to the other electrode of the ferroelectric capacitor. A word line is connected to the gate of the transistor. A bit line is connected to the other electrode of a capacitor and the other end of the transistor, the capacitor having its one electrode connected to the ground. A bit line potential detection circuit detects a potential of the bit line. A connection circuit provides the same potential between a potential of the plate line and a potential of the bit line based on an output from the bit line potential detection circuit.

### CROSS REFERENCE TO RELATED APPLICATIONS

This application is based on and claims the benefit of priority from prior Japanese Patent Application No. 2007-223974, filed on Aug. 30, 2007, the entire contents of which are incorporated herein by reference.

### BACKGROUND OF THE INVENTION

1. Field of the Invention

The present invention relates to a ferroelectric semiconductor storage device, and in particular, to a ferroelectric semiconductor storage device with a plurality of ferroelectric memory cells, each including a ferroelectric capacitor and a transistor connected thereto.

2. Description of the Related Art

An example of semiconductor storage devices is a ferroelectric semiconductor storage device, usually referred to as “ferroelectric memory”, as disclosed in Japanese Patent Laid-Open No. 2002-170380. The ferroelectric memory, which includes ferroelectric capacitors and transistors such as MOS (Metal Oxide Semiconductor)-type field effect transistors, has the gate of each transistor connected to a respective word line and the drain and source of each transistor connected between a respective ferroelectric capacitor and a respective bit line. Each ferroelectric capacitor is configured by forming conductive films on and under a ferroelectric thin film. One of the conductive films is connected to a bit line via the drain and source of a corresponding transistor and the other connected to a plate line of the transistor. The ferroelectric memory has a memory cell that can provide an opposite polarization direction of the ferroelectric capacitor for information “1” and “0”, thereby functioning as a non-volatile memory.

When reading information from the memory cell, the ferroelectric capacitor is connected to a corresponding bit line by initializing the potential of the bit line to the GND potential and then controlling a corresponding word line to cause the transistor to switch to on state. Then, the potential of a corresponding plate line of the ferroelectric capacitor transitions from the GND potential to a predetermined potential. Consequently, those charges polarized to the ferroelectric capacitor move toward the bit line. At this moment, the potential of the bit line may increase either greatly or slightly, according to the state of the polarized charges. Such potential variation in the bit line is read after amplified by a sense amplifier, etc.

In such ferroelectric capacitors, it is necessary to apply a predetermined voltage to obtain a predetermined amount of charges because the amount of accumulated charges varies with the applied voltage.

### SUMMARY OF THE INVENTION

One aspect of the present invention provides a ferroelectric semiconductor storage device comprising: a ferroelectric capacitor; a transistor having one end of its current path connected to one electrode of the ferroelectric capacitor; a plate line connected to the other electrode of the ferroelectric capacitor; a word line connected to the gate of the transistor; a bit line connected to the other electrode of a capacitor and the other end of the current path of the transistor, the capacitor having its one electrode connected to the ground; a bit line potential detection circuit detecting a potential of the bit line; and a connection circuit providing the same potential between the plate line and the bit line based on an output from the bit line potential detection circuit.

Another aspect of the present invention provides a ferroelectric semiconductor storage device comprising: a ferroelectric capacitor; a first transistor having one end of its current path connected to one electrode of the ferroelectric capacitor; a plate line connected to the other electrode of the ferroelectric capacitor; a word line connected to the gate of the first transistor; a bit line connected to the one electrode of a capacitor and the other end of the current path of the first transistor, the capacitor having another electrode connected to the ground; a controller connected to the bit line and signal line, the signal line being provided with a reference potential for comparison with a potential of the bit line; and a second transistor having its gate connected to an output from the controller, one end of its current path being connected to the bit line, and the other end of its current path being connected to the plate line.

### BRIEF DESCRIPTION OF THE DRAWINGS

FIG. 1 is a circuit diagram of a ferroelectric memory cell according to a first embodiment;

FIG. 2 is a time chart of writing information “11” to the ferroelectric memory cell according to the first embodiment;

FIG. 3 is a time chart of writing information “10” to the ferroelectric memory cell according to the first embodiment;

FIG. 4 is an enlarged view illustrating main portions of the time chart of FIG. 3;

FIG. 5 is a time chart of writing information “01” to the ferroelectric memory cell according to the first embodiment;

FIG. 6 is a time chart of writing information “00” to the ferroelectric memory cell according to the first embodiment;

FIG. 7A illustrates a relationship between applied voltage and residual polarization, and FIG. 7B illustrates a relationship between the amount of signal and its distribution;

FIG. 8 is a block diagram of the ferroelectric memory according to the first embodiment;

FIG. 9 illustrates a configuration of an array of ferroelectric memory cells according to the first embodiment; and

FIG. 10 is a circuit diagram of a ferroelectric memory cell according to a second embodiment.

### DETAILED DESCRIPTION OF THE EMBODIMENTS

Embodiments of the present invention will now be described in detail below with reference to the accompanying drawings.

### First Embodiment

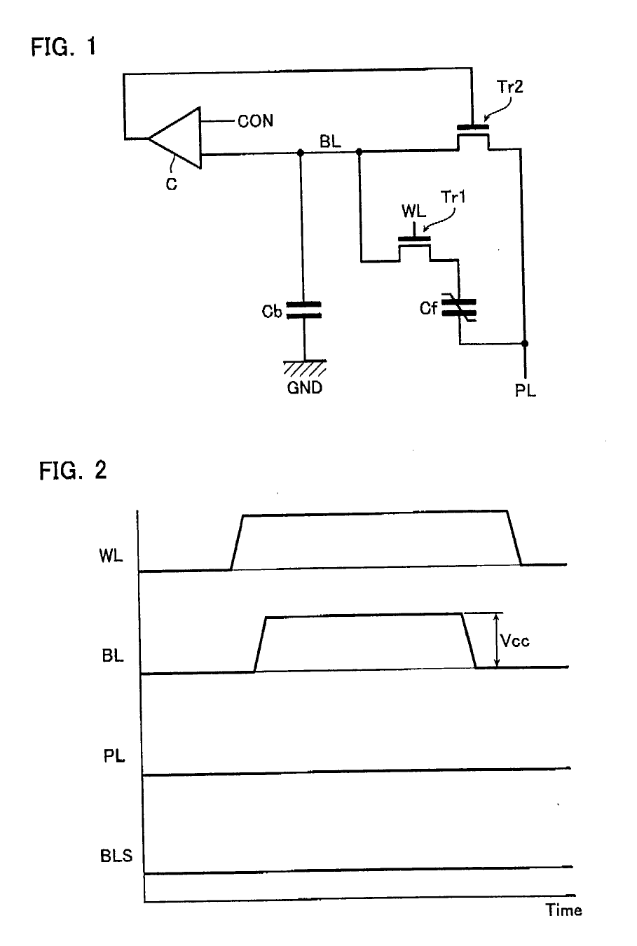

FIG. 1 illustrates a configuration of a ferroelectric memory cell according to a first embodiment. The ferroelectric memory cell of this embodiment includes a MOS-type field effect transistor and a capacitor. Specifically, a MOS-type field effect transistor Tr1 has its gate connected to a word line WL, its source connected to one electrode of a ferroelectric capacitor Cf, and its drain connected to a bit line BL. The other electrode of the ferroelectric capacitor Cf is connected to a plate line PL. In addition, the plate line PL is connected to the source of a MOS-type field effect transistor Tr2, the drain of which is in turn connected to the bit line BL. A capacitor Cb has its one electrode connected to the bit line BL and the other electrode connected to the ground (GND). The bit line is connected to a controller C together with an input signal line CON, which provides input signals to the controller C. The controller C produces output signals based on the input signals. Specifically, the controller C outputs an on signal to bring the MOS-type field effect transistor Tr2 into on state when the potential of the bit line BL becomes higher than that of the input signal line CON. The output from the controller C is connected to the gate of the MOS-type field effect transistor Tr2, bringing the MOS-type field effect transistor Tr2 into on state. As can be seen from the above, one ferroelectric memory cell of this embodiment includes the two MOS-type field effect transistors Tr1 and Tr2, the ferroelectric capacitor Cf, the capacitor Cb, and the controller C.

Based on FIG. 1, the operation of the ferroelectric memory cell of this embodiment will now be described below. Specifically, description is made to an operation for storing four-value data (2-bit information) of multi-value information in one ferroelectric memory cell of this embodiment. In this embodiment, the multi-value information is represented by “00”, “01”, “10”, and “11”.

In the ferroelectric memory cell illustrated in FIG. 1, an electric field is applied to the word line WL that is connected to the ferroelectric memory cell for writing information so that the MOS-type field effect transistor Tr1 turns to on state. Then, Vcc voltage is applied to the bit line BL with the plate line PL connected to the ground (GND). As a result, Vcc voltage is applied across the ferroelectric capacitor Cf, generating polarization P0 in the ferroelectric capacitor Cf. Thereafter, data “11” is written to all of the ferroelectric memory cells.

Then, if the actual data to be written is “11”, as illustrated in FIG. 2, no voltage is applied to the plate line PL and no bit-line detection level signal BLS output from the controller C, while Vcc voltage still applied to the bit line BL. Accordingly, the MOS-type transistor Tr2 will not operate.

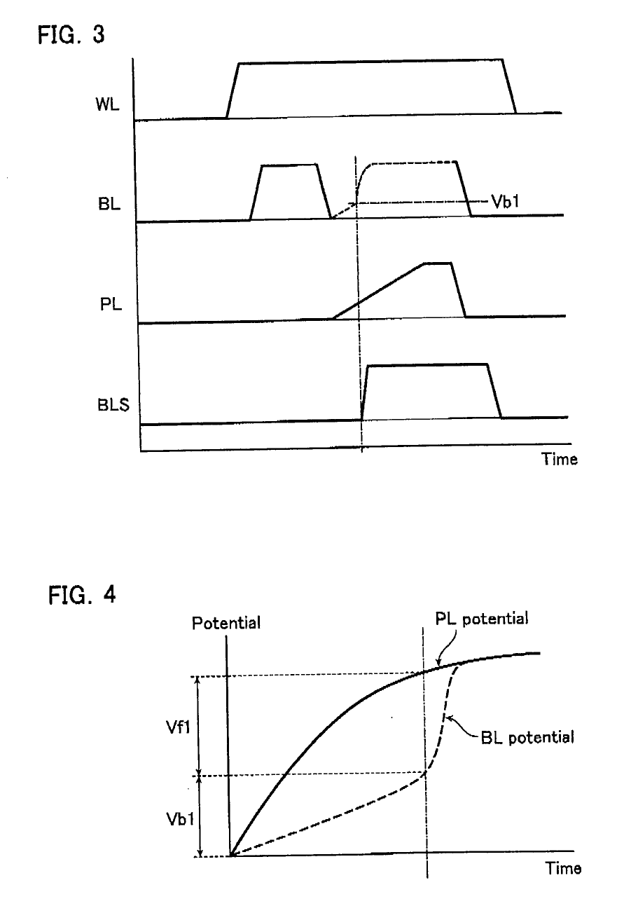

Alternatively, if the written data is “01”, then the bit line BL is brought into floating state as illustrated in FIG. 3. Then, the voltage of the plate line FL is gradually increased so that the ferroelectric capacitor Cf is polarized to store information. Note that while the bit line BL is in floating state, the bit line BL is connected to the ground (GND) via the capacitor Cb, which is a bit-line parasitic capacitance. Thus, the potential of the bit line BL is defined by the amount of charges that move to the bit line BL due to the polarization in the corresponding ferroelectric capacitor reversed by the voltage applied to the plate line PL. That is, since the ferroelectric capacitor Cf and the capacitor Cb are connected in series and the capacitor Cb is connected to the ground, the amount of charges Q that are accumulated in the capacitor Cb is equal to that in the ferroelectric capacitor Cf. Let Va be the voltage applied to the plate line PL, Vb be the potential of the bit line with respect to GND, i.e., the voltage applied across the capacitor Cb, and Vf be the voltage applied across the ferroelectric capacitor Cf, the following equation is obtained:

Q=Cb×Vb=Cf×Vf (1)

Since

Va=Vb+Vf (2)

, the potential of the bit line BL (in this case, the voltage applied across the capacitor Cb) Vb is obtained by the following equation:

Vb=(Va×Cf)/(Cb+Cf) (3)

FIG. 4 illustrates in more detail a relationship between elapsed time and respective potential variation in the plate line PL and the bit line BL. When a bit-line potential Vb is detected by the controller C and if the bit-line potential Vb becomes equal to or more than a potential Vb1 of the input signal line CON, then the controller C immediately outputs an on signal to bring the MOS-type field effect transistor Tr2 into on state. Thus, the potential of the bit line BL is Vb1 immediately before the MOS-type field effect transistor Tr2 turns to on state. At this moment, the potential of the plate line PL is Va1 and the voltage applied across the ferroelectric capacitor Cf is Vf1. When the MOS-type field effect transistor Tr2 turns to on state, the potential of the plate line PL becomes equal to that of the bit line BL and voltage is no longer applied across the ferroelectric capacitor Cf. Accordingly, polarization P1 corresponding to information “10” is maintained that is generated by the voltage Vf1 applied across the ferroelectric capacitor Cf immediately before an on signal is output from the controller C, after which the information is stored.

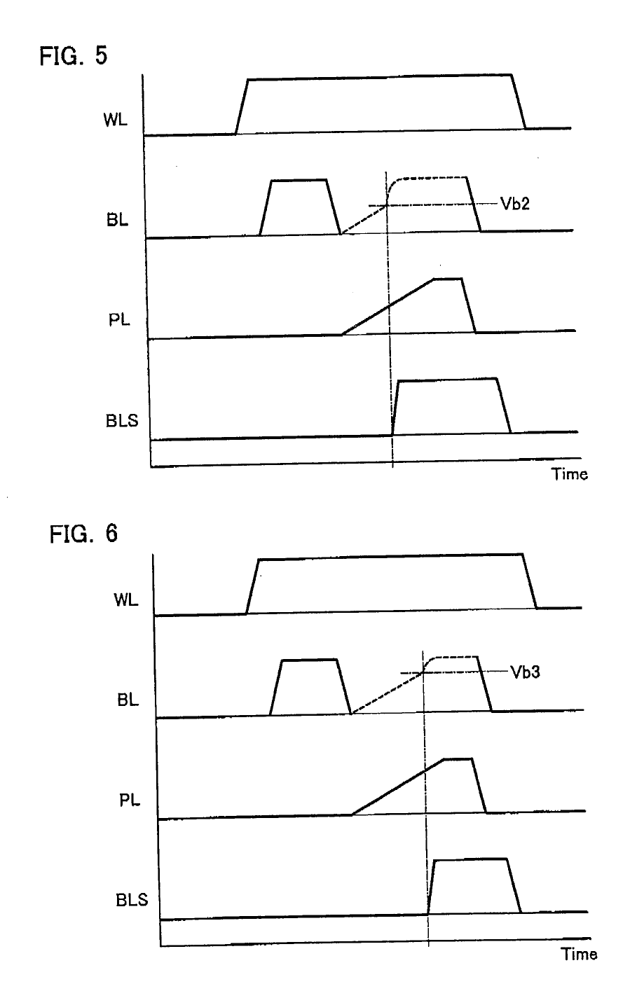

Then, if the written data is “01”, the bit line BL is again brought into floating state as illustrated in FIG. 5, after which the voltage of the plate line PL is gradually increased. This accumulates charges in the ferroelectric capacitor Cf to store information. Note that while the bit line BL is in floating state, the bit line BL is connected to the ground (GND) via the capacitor Cb, which is a bit-line parasitic capacitance. Thus, the potential of the bit line BL is defined by the amount of charges that move to the bit line BL due to the polarization in the corresponding ferroelectric capacitor reversed by the voltage applied to the plate line PL, as in the case specifically described with reference to FIG. 3.

When a bit-line potential Vb is detected by the controller C and if the bit-line potential Vb becomes equal to or more than a potential Vb2 of the input signal line CON, then the controller C immediately outputs an on signal to bring the MOS-type field effect transistor Tr2 into on state. Thus, the potential of the bit line BL is Vb2 immediately before the MOS-type field effect transistor Tr2 turns to on state. At this moment, the potential of the plate line PL is Va2 and the voltage applied across the ferroelectric capacitor Cf is Vf2. When the MOS-type field effect transistor Tr2 turns to on state, the potential of the plate line PL becomes equal to that of the bit line BL and voltage is no longer applied across the ferroelectric capacitor Cf. Accordingly, polarization P2 corresponding to information “01” is maintained that is generated by the voltage Vf2 applied across the ferroelectric capacitor Cf immediately before an on signal is output from the controller C, after which the information is stored.

Then, if the written data is “00”, the bit line BL is again brought into floating state as illustrated in FIG. 6, after which the voltage of the plate line PL is gradually increased. This accumulates charges in the ferroelectric capacitor Cf to store information. Note that while the bit line BL is in floating state, the bit line BL is connected to the ground (GND) via the capacitor Cb, which is a bit-line parasitic capacitance. Thus, the potential of the bit line BL is defined by the amount of charges that move to the bit line BL due to the polarization in the corresponding ferroelectric capacitor reversed by the voltage applied to the plate line PL, as in the case specifically described with reference to FIG. 3.

When a bit-line potential Vb is detected by the controller C and if the bit-line potential Vb becomes equal to or more than a potential Vb3 of the input signal line CON, then the controller C immediately outputs an on signal to bring the MOS-type field effect transistor Tr2 into on state. Thus, the potential of the bit line BL is Vb3 immediately before the MOS-type field effect transistor Tr2 turns to on state. At this moment, the potential of the plate line PL is Va3 and the voltage applied across the ferroelectric capacitor Cf is Vf3. When the MOS-type field effect transistor Tr2 turns to on state, the potential of the plate line PL becomes equal to that of the bit line BL and voltage is no longer applied across the ferroelectric capacitor Cf. Accordingly, polarization P3 corresponding to information “00” is maintained that is generated by the voltage Vf3 applied across the ferroelectric capacitor Cf immediately before an on signal is output from the controller C, after which the information is stored.

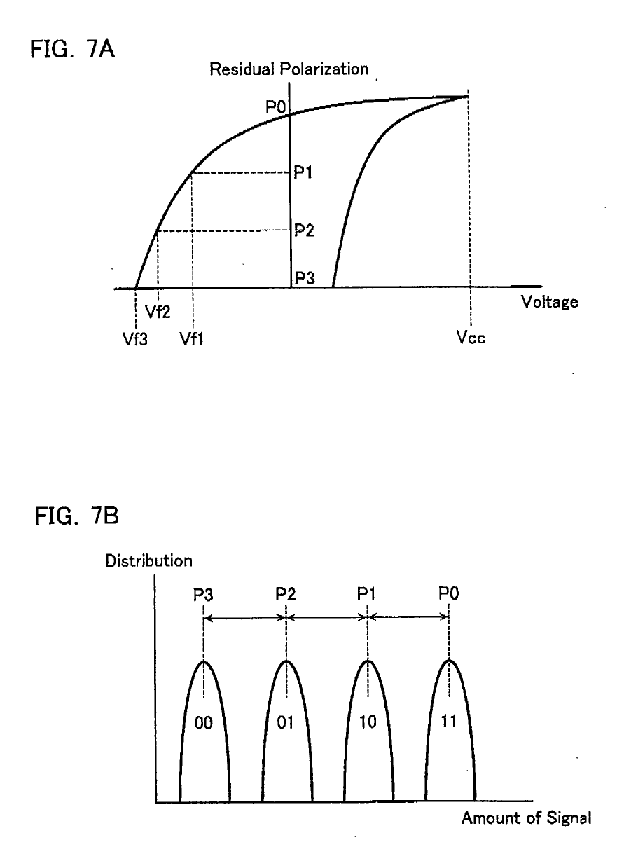

FIG. 7A illustrates a relationship between applied voltage and residual polarization, and FIG. 7B illustrates a relationship between the amount of signal and its multi-value distribution. Firstly, when Vcc voltage is applied to the bit line BL with the plate line PL connected to the ground (GND), the ferroelectric capacitor Cf maintains such polarization state even after polarization P0 is caused and application of voltage is stopped therein. In this embodiment, information “11” is stored where polarization P0 is caused in the ferroelectric capacitor Cf.

Then, as mentioned earlier, when the voltage applied across the ferroelectric capacitor Cf becomes Vf1, i.e., as illustrated in FIG. 3, when the potential of the input signal line CON becomes Vb1 after voltage is applied to the plate line PL, the ferroelectric capacitor Cf maintains such polarization state even after polarization P1 is caused and application of voltage is stopped therein. In this embodiment, information “10” is stored where polarization P1 is caused in the ferroelectric capacitor Cf.

In addition, as mentioned earlier, when the voltage applied across the ferroelectric capacitor Cf becomes Vf2, i.e., as illustrated in FIG. 5, when the potential of the input signal line CON becomes Vb2 after voltage is applied to the plate line PL, the ferroelectric capacitor Cf maintains such polarization state even after polarization P2 is caused and application of voltage is stopped therein. In this embodiment, information “01” is stored where polarization P2 is caused in the ferroelectric capacitor Cf.

In addition, as mentioned earlier, when the voltage applied across the ferroelectric capacitor Cf becomes Vf3, i.e., as illustrated in FIG. 6, the potential of the input signal line CON becomes Vb3 after voltage is applied to the plate line PL, the ferroelectric capacitor Cf maintains such polarization state even after polarization P3 is caused and application of voltage is stopped therein. In this embodiment, information “00” is stored where polarization P3 is caused in the ferroelectric capacitor Cf. As can be seen from the above, multi-value information may be accurately stored in the ferroelectric memory cell.

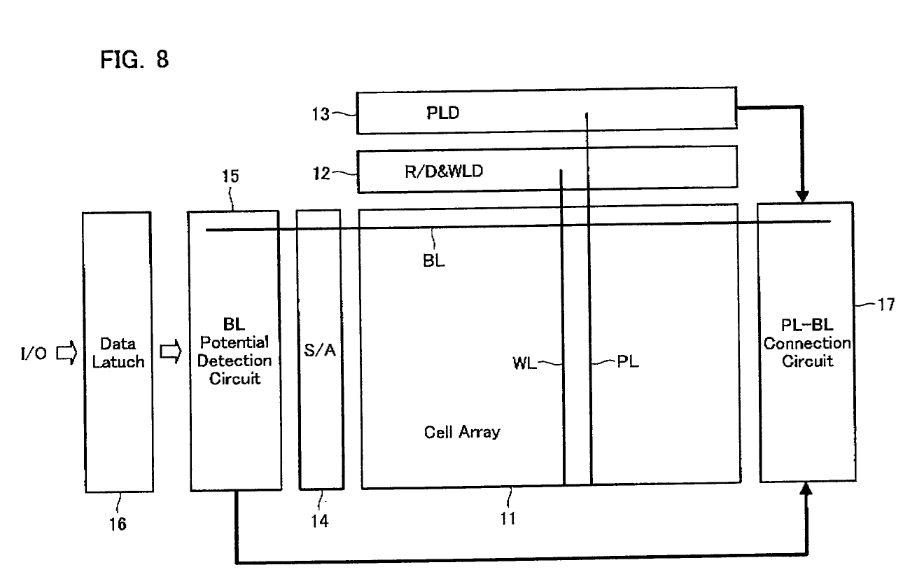

FIG. 8 is a block diagram of a FeRAM including the above-mentioned ferroelectric memory. Specifically, a row driver 12 that includes a row decoder (R/D) and a word line driver (WLD) and a plate line driver (PLD) 13 are provided in the row direction of a cell array 11 wherein ferroelectric memory cells are arranged in a two-dimensional fashion. The row driver 12 is connected to the memory cell array 11 via a word line WL, while the plate line driver (PLD) 13 is connected to the memory cell array 11 via a plate line PL.

On the other hand, a sense amplifier 14 and a bit line (BL) potential detection circuit 15 are provided in the column direction, and they are also connected to the memory cell array 11 via the bit line BL, respectively. Input signals for control or data are input to the bit line (BL) potential detection circuit 15 from I/O via a data latch 16. In addition, respective outputs of the bit line (BL) potential detection circuit 15 and the plate line driver (PLD) are input to a PL-BL connection circuit 17. Note that the bit line (BL) potential detection circuit 15 is configured by the controller C of FIG. 1 and the PL-BL connection circuit 17 is configured by the MOS-type field effect transistor Tr2 of FIG. 1.

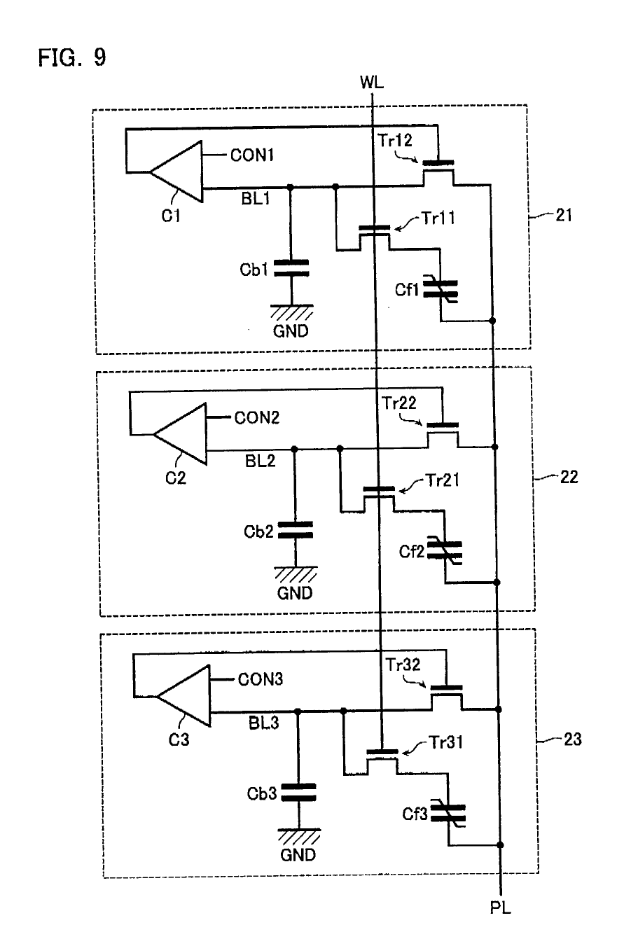

Based on FIG. 9, the ferroelectric memory of this embodiment will now be described in detail below. The ferroelectric memory of this embodiment has a plurality of ferroelectric memory cells provided therein that share one word line WL and one plate line PL. Similar to the configuration mentioned above, ferroelectric memory cells 21, 22 and 23 have the following components provided therein: MOS-type field effect transistors Tr11, Tr21 and Tr31, each connected to ferroelectric capacitors Cf1, Cf2 and Cf3, capacitors Cb1, Cb2 and Cb3, MOS-type field effect transistors Tr12, Tr22 and Tr32, and controllers C1, C2 and C3. Note that other plurality of ferroelectric memory cells with similar configuration that share bit lines (BL1, BL2 and BL3) are arranged in the lateral direction of FIG. 9.

In this embodiment, different information may be stored in each of the ferroelectric memory cells at the same time. That is, if one page normally includes a plurality of ferroelectric memory cells and if what information is written to the ferroelectric memory cells is controlled by the potential of the plate line PL, then information can be written only on a page by page basis because the plate line PL is shared among the ferroelectric memory cells in that page. In this embodiment, however, different information can be individually written to the ferroelectric memory cells in the same page that share the plate line PL.

Specifically, providing different potentials for respective input signal lines CON1, CON2 and CON3 of the controllers C1, C2 and C3, such information corresponding to the potentials applied to the input signal lines CON1, CON2 and CON3 may be written to the respective ferroelectric capacitors Cf1, Cf2 and Cf3 as multi-value information due to the different amount of polarization. Accordingly, when multi-value information should be written to one ferroelectric memory cell fast enough, improved writing speed can be obtained.

### Second Embodiment

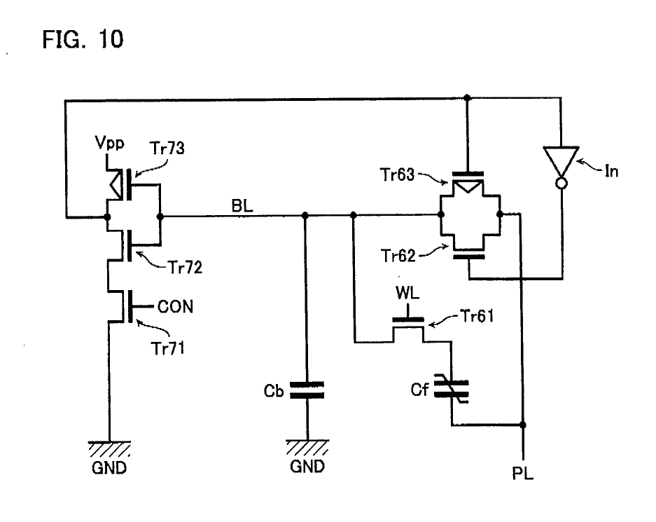

According to a second embodiment, a controller C includes three MOS-type field effect transistors. This embodiment will now be described below based on FIG. 10. The ferroelectric memory cell of this embodiment includes MOS-type field effect transistors and capacitors.

Specifically, a MOS-type field effect transistor Tr61 has its gate connected to a word line WL, its source connected to one electrode of a ferroelectric capacitor Cf, and its drain connected to a bit line BL. The other electrode of the ferroelectric capacitor Cf is connected to a plate line PL. In addition, the plate line PL is connected to respective sources of an n-type MOS-type field effect transistor Tr62 and a p-type MOS-type field effect transistor Tr63, and their drains are connected the bit line BL, respectively. The capacitor Cb has one electrode connected to the bit line BL and the other electrode connected to the ground (GND). The controller has a p-type MOS-type field effect transistor Tr73, an n-type MOS-type field effect transistor Tr72, and an n-type MOS-type field effect transistor Tr71 connected in series. The source of the p-type MOS-type field effect transistor Tr73 is connected to a power supply Vpp and the drain of the n-type MOS-type field effect transistor Tr71 is connected to the ground (GND). The respective gates of the p-type MOS-type field effect transistor Tr73 and the n-type MOS-type field effect transistor Tr72 are connected to the bit line BL. Note that the p-type MOS-type field effect transistor Tr73 and the n-type MOS-type field effect transistor Tr72 together configure an inverter circuit. In addition, an input signal line CON is connected the gate of the n-type MOS-type field effect transistor Tr71.

In this embodiment, description is made to a case where 2-bit information is stored in one memory cell, i.e., 4-value storage. In writing information, stored information in the ferroelectric capacitor Cf can be controlled by setting three potentials at the input signal line CON. Specifically, if low potentials are input to the input signal line CON, then inverted outputs are output from the p-type MOS-type field effect transistor Tr73 and the n-type MOS-type field effect transistor Tr72 that are connected in series, even if low potentials are presented at the bit line BL. The inverted outputs may be input via the gate of the p-type MOS-type field effect transistor Tr63 and an inverter In to the gate of the n-type MOS-type field effect transistor Tr62, may connect the plate line PL to the bit line BL, and may provide the same potential between the bit line BL and the plate line PL.

Alternatively, if high potentials are input to the input signal line CON, then no inverted outputs are output from the p-type MOS-type field effect transistor Tr73 and the n-type MOS-type field effect transistor Tr72 that are connected in series, as long as high potentials are not presented at the bit line BL.

Therefore, multiple values may be stored in the ferroelectric memory cell of this embodiment by inputting three potentials with different values to the input signal line CON corresponding to information “10”, “01” and “00” to be stored, respectively. Note that regarding the ferroelectric memory cell of this embodiment, a ferroelectric memory may also be configured by an array of ferroelectric memory cells, as in the first embodiment.

While the ferroelectric semiconductor storage device according to the present invention has been specifically described with reference to illustrative embodiments, the invention is also applicable to other cases where information with more than two bit is to be stored in one memory cell. In addition, the present invention is not intended to be limited to the above embodiments and may take any other forms than those specifically disclosed herein.

What is claimed is:

1. A ferroelectric semiconductor storage device comprising:
a ferroelectric capacitor;
a transistor having one end of its current path connected to one electrode of the ferroelectric capacitor;
a plate line connected to the other electrode of the ferroelectric capacitor;
a word line connected to the gate of the transistor;
a bit line connected to the other electrode of a capacitor and the other end of the current path of the transistor, the capacitor having its one electrode connected to the ground;
a bit line potential detection circuit detecting a potential of the bit line; and
a connection circuit providing the same potential between the plate line and the bit line based on an output from the bit line potential detection circuit.

2. The ferroelectric semiconductor storage device according to claim 1, wherein
in storing information in the ferroelectric capacitor, positive voltage with respect to a plate line is applied to a bit line before the bit line is brought into floating state, and then
positive voltage with respect to the ground is applied to the plate line with a gradual increase in the applied positive voltage.

3. The ferroelectric semiconductor storage device according to claim 1, wherein
the connection circuit is a transistor that is connected to form a current path between the plate line and the bit line and that becomes conductive based on an output from the bit line potential detection circuit.

4. The ferroelectric semiconductor storage device according to claim 1, wherein
the bit line potential detection circuit detects a magnitude relation between a potential of the bit line and a reference potential.

5. The ferroelectric semiconductor storage device according to claim 4, wherein
the ferroelectric semiconductor storage device is configured to store multi-value information in a memory cell including the ferroelectric capacitor and the transistor by changing the magnitude of the reference potential.

6. The ferroelectric semiconductor storage device according to claim 1, wherein
the bit line potential detection circuit operates the connection circuit to provide the same potential between the plate line and the bit line when a potential of the bit line becomes equal to or more than a predetermined value.

7. The ferroelectric semiconductor storage device according to claim 1, wherein
the bit line potential detection circuit comprises a PMOS transistor, a first NMOS transistor, and a second NMOS transistor, each connected in series between a power supply terminal and a ground terminal,
the respective gates of the PMOS transistor and the first NMOS transistor are connected to the bit line,
a reference potential is supplied to the gate of the second NMOS transistor, and
a connection point between the PMOS transistor and the first NMOS transistor provides an output terminal.

8. The ferroelectric semiconductor storage device according to claim 1, wherein
the connection circuit includes a PMOS transistor and an NMOS transistor connected in parallel between the bit line and the plate line.

9. A ferroelectric semiconductor storage device comprising:
a ferroelectric capacitor;
a first transistor having one end of its current path connected to one electrode of the ferroelectric capacitor;
a plate line connected to the other electrode of the ferroelectric capacitor;
a word line connected to the gate of the first transistor;
a bit line connected to the one electrode of a capacitor and the other end of the current path of the first transistor, the capacitor having another electrode connected to the ground;
a controller connected to the bit line and signal line, the signal line being provided with a reference potential for comparison with a potential of the bit line; and
a second transistor having its gate connected to an output from the controller, one end of its current path being connected to the bit line, and the other end of its current path being connected to the plate line.

10. The ferroelectric semiconductor storage device according to claim 9, wherein
the controller outputs a signal to bring the second transistor into on state when a potential of the bit line becomes equal to or more than the reference potential input to the signal line.

11. The ferroelectric semiconductor storage device according to claim 9, wherein
a signal input to the signal line includes selected one of a plurality of potentials, and
information with more than one bit is stored in one ferroelectric capacitor by changing the amount of polarization in the ferroelectric capacitor based on a potential of the signal line.

12. The ferroelectric semiconductor storage device according to claim 9, wherein
in storing information in the ferroelectric capacitor, a voltage larger than a potential of the plate line is applied to the bit line before the bit line is brought into floating state, and then
positive voltage with respect to the ground is applied to the plate line with a gradual increase in the applied positive voltage.

13. The ferroelectric semiconductor storage device according to claim 9, wherein
the controller comprises a PMOS transistor, a first NMOS transistor, and a second NMOS transistor connected in series between a power supply terminal and a ground terminal,
the gate of the PMOS transistor and the gate of the first NMOS transistor are connected to the bit line,
a reference potential is supplied to the gate of the second NMOS transistor,
a connection point between the PMOS transistor and the first NMOS transistor serves as an output terminal.

14. The ferroelectric semiconductor storage device according to claim 9, wherein
the second transistor includes a PMOS transistor and an NMOS transistor connected in parallel between each of the bit line and the plate line.
